(19) United States
(12) Patent Application Publication
(10) Pub. No.: US 2026/0299541 A1
(43) Pub. Date: Oct. 1, 2026

(54) TRUSS ASSEMBLY USING METAL PLATES

(71) Applicant: Simpson Strong-Tie Company Inc., Pleasanton, CA (US)

(72) Inventors: David MERL, Pleasanton, CA (US); Christian WOLFF, Pleasanton, CA (US); Teesh YALAMANCHILI, Pleasanton, CA (US)

(73) Assignee: Simpson Strong-Tie Company Inc., (omitted)

(21) Appl. No.: 19/576,831

(22) Filed: Mar. 24, 2026

Related U.S. Application Data
(60) Provisional application No. 63/777,332, filed on Mar. 25, 2025.

(51) Int. Cl. G05B 19/042; E04C 3/16

(52) U.S. Cl. CPC G05B 19/0423; E04C 3/16; G05B 2219/24088

(57) ABSTRACT

A method for assembling a wood truss using truss plates with predefined placements is disclosed. The method includes generating construction drawings that depict graphical representations of truss plates, including the positions and orientations of their teeth relative to the junctions of truss components. The truss components are positioned on a work surface according to the drawings, and truss plates corresponding to the graphical representations are aligned with each junction. Pressure is then applied to secure the plates, ensuring structural integrity. The truss plates include a plurality of teeth punched in pairs and formed at right angles to the plate face, with rows of punched holes represented in the construction drawings. This method enhances precision in truss assembly, reducing errors and improving manufacturing efficiency.

### CLAIM OF PRIORITY

This application claims priority to U.S. Provisional Patent Application No. 63/777,332 entitled “TRUSS ASSEMBLY USING METAL PLATES”, filed Mar. 25, 2025, which application is incorporated by reference herein in its entirety.

### FIELD

The following is related generally to the field wood truss assembly techniques.

### BACKGROUND

Truss plates are used to join components of a truss assembly (planks of lumber) that form wood trusses, such as floor and roof trusses, used in commercial and residential construction. Truss plates typically comprise a backing plate (or face) and an array of sharp spike-like prongs or impaling members that extend outwardly from the backing plate. Adjacent planks of a truss with coplanar surfaces can be permanently joined by pounding or pressing the backing member of a truss plate so that its impaling members penetrate the planks.

Positioning truss plates accurately with respect to the truss assembly components is critical for the structural integrity of the wood truss. Several issues can arise during manufacturing, leading to weakened connections and potential structural failures. These issues can include plate misalignment, incorrect orientation, incorrect positioning, or incorrect plate selection. If misalignment occurs, this can reduce the ability of the component wood members of the truss to transfer loads effectively. Incorrect plate orientation can result in uneven force distribution, reducing the joint's strength. Incorrect plate selection may occur when different plate types (regular vs. high strength) are similar in appearance. Incorrect plate selection can also compromise the integrity of the assembly.

### SUMMARY

One general aspect includes a method of assembling a wood truss having truss components which are joined by truss plates. The method includes generating construction drawings including graphical representations of the plurality of teeth at positions and orientations relative to junctions between components to which the plate is to be secured in an assembled wood truss. The method also includes placing the truss components in positions as illustrated in the drawings on a work surface and aligning a truss plate matching the graphical representation of the plurality of teeth for each of the junctions between truss components to be secured. The method also includes applying pressure to each plate to secure each junction.

Implementations may include a method where each truss plate includes a surface having a face, where the plurality of teeth are punched from the truss plate in pairs of teeth and formed at right angles to the face of the plate so that two teeth per hole occur in rows along the face. Implementations may include a method incorporating any of the previous steps wherein each graphical representation of the truss plate includes a representation of each punched hole of the pairs of teeth. Implementations may include a method incorporating any of the previous steps wherein each graphical representation of the truss plate includes a representation of each punched hole of the pairs of teeth Implementations may include a method incorporating any of the previous steps wherein each graphical representation of the truss plate includes a representation of each punched hole of the pairs of teeth. Implementations may include a method incorporating any of the previous steps wherein each graphical representation of the truss plate includes a representation of each punched hole of the pairs of teeth wherein placing may include: printing the construction drawings, and aligning the truss plate by matching the placement and orientation of the teeth of each truss plate to the graphical representation of the respective plate on the printed construction drawings. Implementations may include a method incorporating any of the previous steps wherein each graphical representation of the truss plate includes a representation of each punched hole of the pairs of teeth the placing may include: rendering the construction drawings on a graphical display, and aligning the truss plate by matching the placement and orientation of the teeth of each truss plate to the rendered drawing of the respective plate. Implementations may include a method incorporating any of the previous steps wherein each graphical representation of the truss plate includes a representation of each punched hole of the pairs of teeth the placing may include: rendering the construction drawings on a graphical projector display, and aligning the truss plate by matching the placement and orientation of the teeth of each truss plate to the rendered drawing on the graphical projector display. Implementations may include a method incorporating any of the previous steps wherein each graphical representation of the truss plate includes a representation of each punched hole of the pairs of teeth the method further includes: printing truss plate teeth positions on the components, and aligning the truss plate by matching the placement and orientation of the plate to the printed positions on the components. Implementations may include a method incorporating any of the previous steps wherein each graphical representation of the truss plate includes a representation of each punched hole of the pairs of teeth the rendering may include printing truss plate pin positions on the components to allow the assembler to align each of the truss plates by matching the placement and orientation of the plate to the printed positions on the components.

Another general aspect includes a computer implemented method of assembling a wood truss having truss components secured by truss plates. The computer implemented method includes designing a construction project including one or more wood trusses, and a plurality of truss plate types each having a plurality of teeth. The method also includes creating, in a computer implemented truss design system, a graphical model of the positions of teeth relative to the face of the each truss plate type. The method also includes storing the graphical model of each truss plate type in a data library and, in the computer implemented truss design system, for each truss plate in a truss assembly in the construction project, retrieving the graphical model and rendering teeth marks on a construction drawing, the teeth markings corresponding to the position and orientation of the teeth. The method also includes rendering the drawing to an display to allow a truss assembler to construct the truss assembly.

Implementations may include a method incorporating any of the previous steps wherein each graphical representation of the truss plate includes a representation of each punched hole of the pairs of teeth. Implementations may include a method incorporating any of the previous steps wherein each graphical representation of the truss plate includes a representation of each punched hole of the pairs of teeth where each truss plate includes a surface having a face and the teeth are punched from the truss plate in pairs and formed at right angles to the face of the parent metal so that two teeth per hole occur in rows along the face. Implementations may include a method incorporating any of the previous steps wherein each graphical representation of the truss plate includes a representation of each punched hole of the pairs of teeth wherein each graphical representation of the truss plate includes a representation of each of the punched portion of the pairs of teeth. Implementations may include a method incorporating any of the previous steps wherein each graphical representation of the truss plate includes a representation of each punched hole of the pairs of teeth wherein the rendering may include: printing the construction drawings to allow the assembler to align each of the truss plates by matching the placement and orientation of the plate to the printed construction drawings. Implementations may include a method incorporating any of the previous steps wherein each graphical representation of the truss plate includes a representation of each punched hole of the pairs of teeth wherein the rendering may include: rendering the construction drawings on a graphical display to allow the assembler to align each of the truss plates by matching the placement and orientation of the plate to rendered construction drawings on the graphical display. Implementations may include a method incorporating any of the previous steps wherein each graphical representation of the truss plate includes a representation of each punched hole of the pairs of teeth wherein the rendering may include: rendering the construction drawings on a projection display to allow the assembler to align each of the truss plates by matching the placement and orientation of the plate to rendered construction drawings on the projection display.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

Aspects of the present disclosure are illustrated by way of example and are not limited by the accompanying Figures for which like references indicate elements.

FIG. 1 is a plan view of a typical truss assembly using truss plates.

FIG. 2A is a perspective view of a typical truss plate used in a truss assembly.

FIG. 2B is a top view of the truss plate of FIG. 2A.

FIG. 2C is a left-side view relative to FIG. 2B.

FIG. 2D is a bottom view relative to FIG. 2B.

FIG. 3 is a typical truss plate construction drawing having plate offset instructions and illustrating an enlarged view of a truss plate joining components of the truss assembly.

FIG. 4 is a flow chart illustrating a typical truss assembly method.

FIG. 5A is a flow chart illustrating a truss assembly method in accordance with the described embodiments.

FIG. 5B is a flow chart illustrating an alternative truss assembly method in accordance with the described embodiments.

FIG. 6 illustrates a construction drawing in accordance with the disclosed embodiments showing an enlarged portion of the drawing and showing teeth positioning relative to the truss joints.

FIG. 7 is a flow chart illustrating an embodiment of a computer implemented drawing method in accordance with the disclosed embodiments.

FIG. 8 illustrates an enlarged portion of construction drawing in accordance with the disclosed embodiments showing a first alternative to the illustration in FIG. 3.

FIG. 9 illustrates an enlarged portion of construction drawing in accordance with the disclosed embodiments showing a second alternative to the illustration in FIG. 3.

FIG. 10 illustrates an enlarged portion of construction drawing in accordance with the disclosed embodiments showing a third alternative to the illustration in FIG. 3.

FIG. 11 is a block diagram of network processing device suitable for creating construction drawings in accordance with the described embodiments.

### DETAILED DESCRIPTION

Techniques are described for constructing truss assemblies.

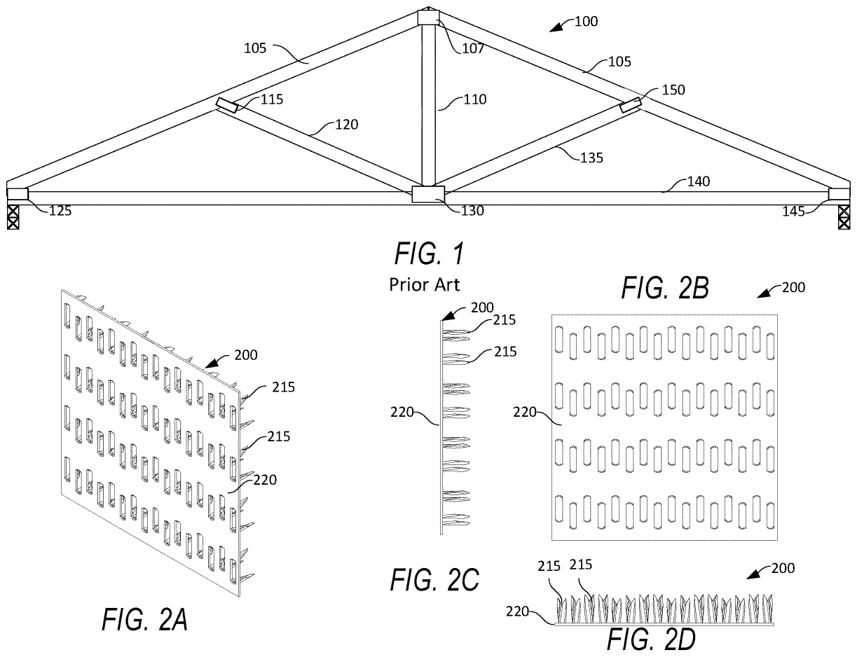

FIG. 1 is a plan view of a typical roof truss assembly 100. The assembly 100 includes a number of components comprising two top chords 105, bottom chord 140, webs 120, 135, and king post 110. The wood components are cut to specifications provided by the truss designer, and truss plates 107, 115, 125, 130, 145, 150 are used to join the components.

FIG. 2A is a perspective view of a typical truss plate used in a truss assembly. FIG. 2B is a top view of the truss plate of FIG. 2A. FIG. 2C is a left-side view relative to FIG. 2B. FIG. 2D is a bottom view relative to FIG. 2B.

As illustrated in FIG. 2A-2D, a plate 200 typically comprise a backing plate 220 and an array of sharp prongs or teeth 215 that extend outwardly from the backing plate. Adjacent planks of a truss with coplanar surfaces can be permanently joined by pounding or pressing the backing member of a truss plate so that its impaling members penetrate the planks. In embodiments, each truss plate in the described embodiments each truss plate includes a surface having a back side and a face, and a plurality of teeth which are punched from back surface in pairs of teeth and formed at right angles to the face of the plate so that two teeth on either side of the puncher hole occur, with each hole elongated and multiple holes formed in rows along the face.

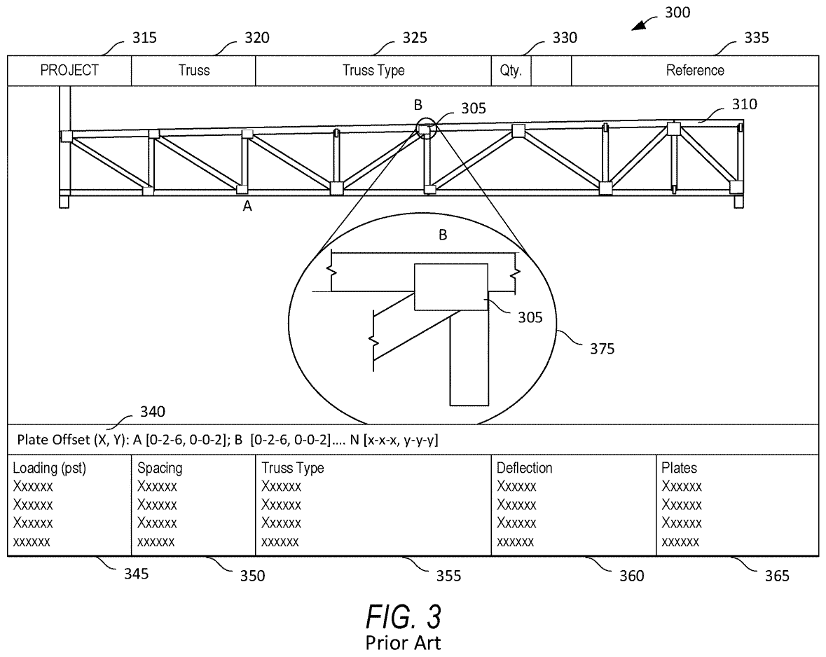

FIG. 3 is a typical truss plate construction drawing 300. An enlarged view of a truss plate 300 joining components of the truss assembly 310 shows the orientation of the truss plate to the joint at which the components are joined. As shown in FIG. 3, drawing 300 provides a detailed representation of the structural components, and connection details of trusses used in a building project. Other drawings provide the placement details of the assembly in the context of the project as a whole. The drawing 300 includes general information such as the project name 315, truss name 320, truss type 325, quantity to be produced 330, and drawing reference 335. It may also include loading information 345, truss spacing (i.e., truss size) 350, truss type 355, deflection 360 and plate specifications 365. In FIG. 3, the plan view or layout shown in FIG. 3 illustrates the top-down positioning of components an plates in the truss assembly. This includes reference points for plate alignment, and identification tags (A, B) corresponding to specific truss plates to be used.

As noted, positioning truss plates accurately is critical for the structural integrity of the wood truss assembly. In accordance with known techniques, the drawing includes plate offset instructions 340 to allow assembly workers to correctly position truss plates. In the context of metal connector plates in wood trusses, “plate offsets” refer to the specific placement of the plate relative to the center of the joint, where the truss members (components) meet. They ensure proper load transfer and function of the truss, impacting the effective teeth engagement and bearing area.

As illustrated in the enlarged portion 375 of the drawing, a truss plate 305 is shown relative to the components it joins, and assembly personnel will use the offset data in the drawing 300 to complete assembly of the truss.

In a manufacturing environment, plate offsets can be difficult to use. Truss assembly personnel are under pressure to create trusses quickly and efficiently. Assembly personnel may make errors in the placement of truss plates or in the selection of the correct truss plates. Truss plates are generally rectangular or square and sometimes have a similar appearance to each other, but may come in a regular strength and high strength varieties. Incorrect use of a regular strength truss plate may compromise the integrity of the truss assembly.

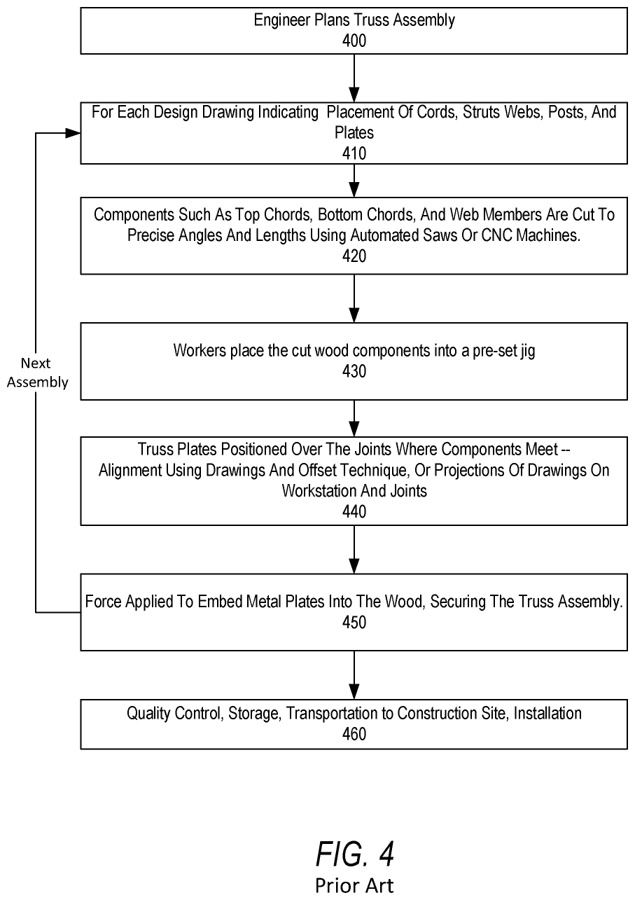

FIG. 4 illustrates a conventional truss plate assembly method. At 400, a structural engineer creating a building design will design each trust assembly in accordance with the particular construction project. A complete design will have each trust assembly will appear in a construction drawing in a manner similar to that shown at FIG. 3, indicating the placement of cords come with struts, website, posts and trust plates. At 410, the method may occur for each drawing (or for each truss assembly specified by a drawing or series of drawings). At 420 components such as top cords, bottom chords and web members are cut to precise angles and lengths using an automated saw or computer-controlled machine tool. At 430, workers place the components into a preset jig or other work surface for assembly. At 440, truss plates are positioned over the joints where the components meet according to the construction drawings. Plates are aligned using, for example, the offsets specified in the drawings. In some instances, this is done by workers attempting to visually align the plate relative to a printed drawing. In other cases, the drawing may be enlarged and projected onto the assembly station in order to allow workers to improve the visual alignment. Once the truss plates are positioned, at 450, force applied to the metal plates to force the plates into the woods, securing the truss assembly. At 460, quality control measures are implemented, and the assemblies are stored and/or transported to the construction site.

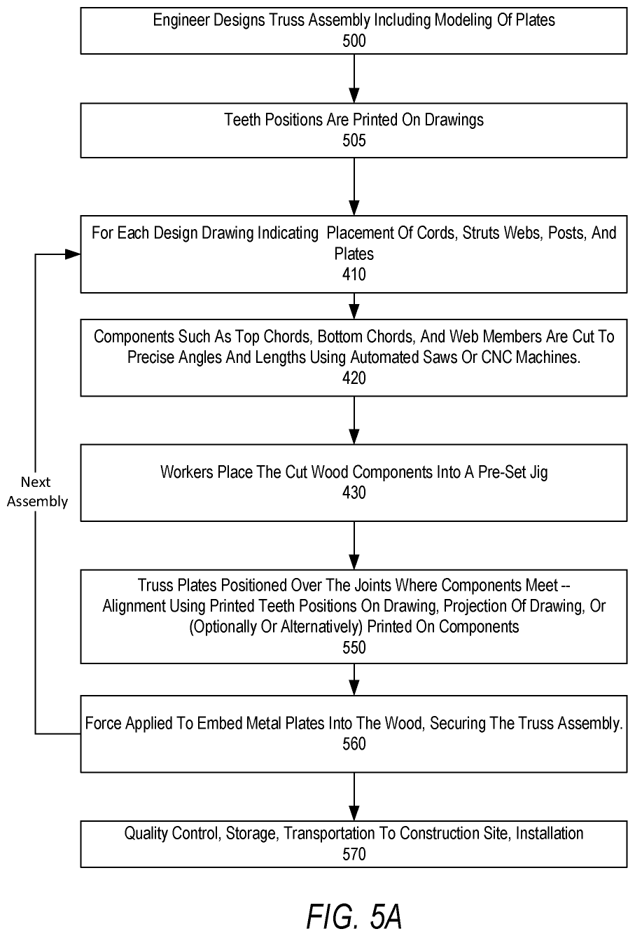

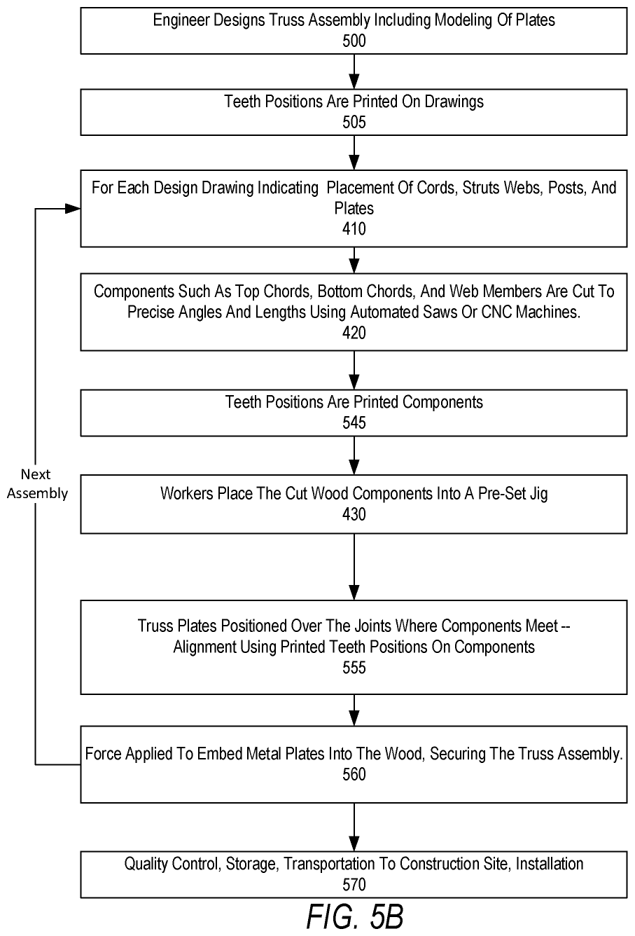

FIG. 5A is a flow chart illustrating a truss assembly method in accordance with the described embodiments where like numbered steps are equivalent to those in previous drawings. At 500, a structural engineer creating a building design will design each trust assembly in accordance with the particular construction project. At 500, engineer will place a drawing model of the truss plate teeth pattern associated with the specified truss plate at the correct position and orientation of the position of the plate relative to the components it is designed to join. In one alternative, the design occurs in software and each plate includes as associated model of teeth placements such that placement of the plate aligns the teeth with respect to orientation and position relative to the components.

In one embodiment, at 505, teeth positions are printed on the drawings at 505. In this context, “printed” means actual printing on paper, rendering on a computer display, rendering in an augmented reality device, or projected onto components from an overhead projector.

Steps 410 and 420 proceed as in FIG. 4: for each drawing of a truss assembly at 410, components are cut at 420. At 430, the components are laid out in a pre-set jig. At 550, the truss plates are positioned or aligned over the joints of components to be connected using the teeth positions on the drawing or rendering of the drawing. This allows workers to precisely align the plates based on the position and orientation of individual teeth. This also avoids confusion in the selection and placement of truss plates, all of which are rectangular or square, since the truss plate teeth placement must align to the drawing, rather than just aligning the outside boundary of the plates.

FIG. 5B is a flow chart illustrating an alternative assembly method where like numbered steps are equivalent to those in previous drawings. In FIG. 5B, the teeth positions are optionally printed on the components themselves at 545. This may be performed by an automated computer numerical control (CNC) machines combined with inkjet printing, a labeling or printing system or an engraving system.

At 555, truss plates positioned over the joints where components meet and workers align the plates using the printed teeth positions on the components.

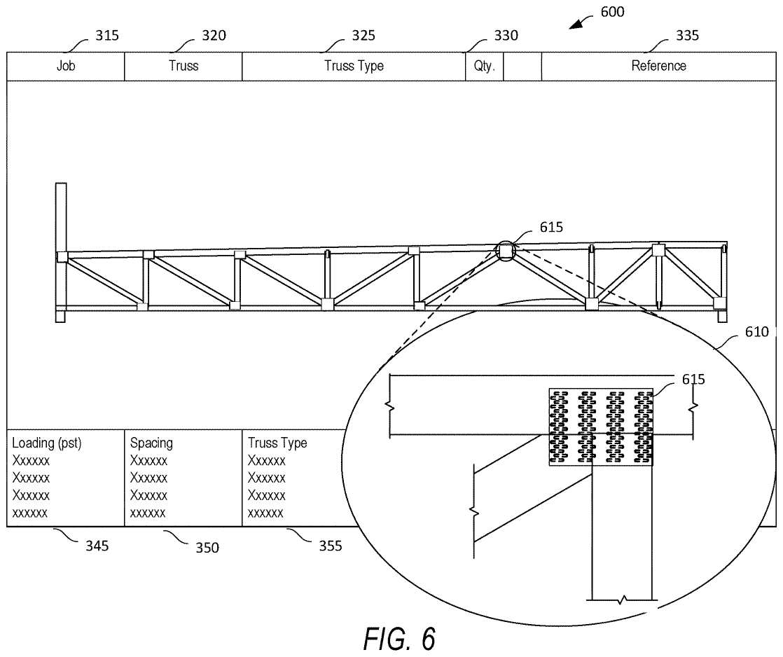

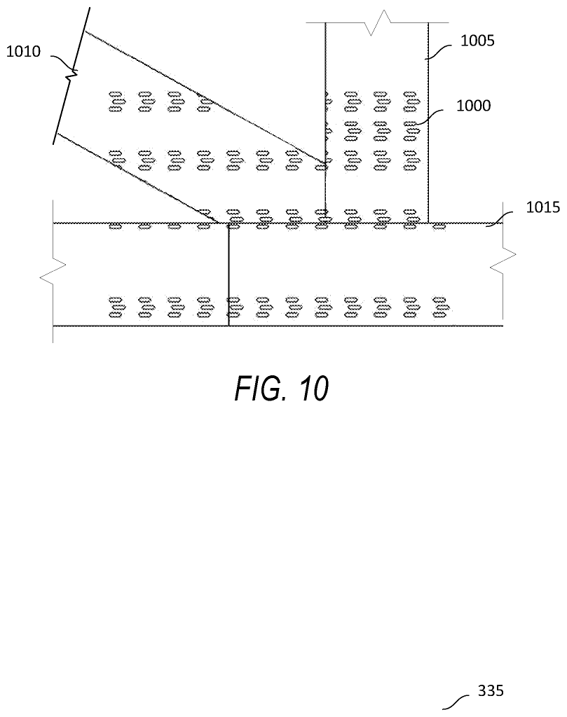

FIG. 6 illustrates a construction drawing 600 in accordance with the disclosed embodiments showing an enlarged portion 610 of the drawing and showing teeth positioning relative to the truss joints. Like numbered parts are equivalent to those in previous drawings. Truss plate illustration 615 includes the position and orientation of the truss plate teeth. In embodiments, the border (edges) of the truss plate are illustrated. In other embodiments, only the teeth and slot orientation are shown (as is shown, for example, in FIG. 10).

FIGS. 6, 8-10 illustrate teeth positioning relative to a each truss plate such as that shown in FIG. 2A-2D where a plurality of teeth are punched from the truss plate in pairs of teeth and formed at right angles to the face of the plate so that two teeth form a slot, and a number of slots are arranged in rows on the plate. In these examples, the graphical representation of the teeth includes a representation of each punched hole of the pairs of teeth. It should be understood that other embodiments and graphical representations for different types of truss plates and teeth configurations (for example, those not having the aforementioned slots) can be used with the present methods.

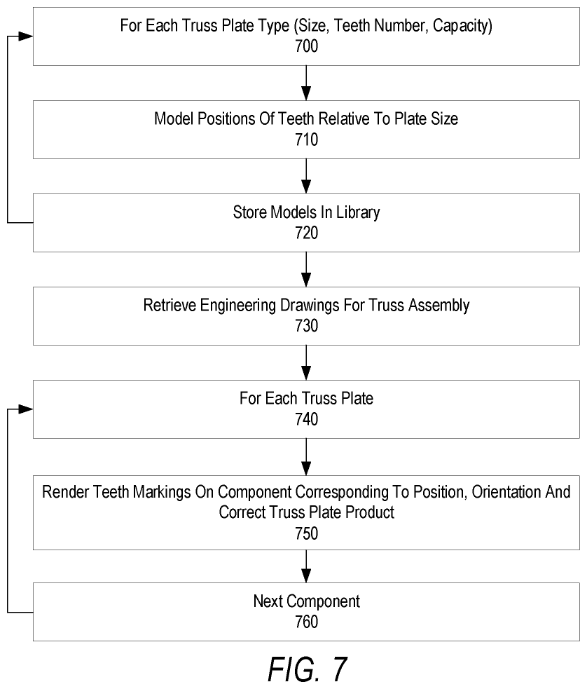

FIG. 7 is a flow chart illustrating an embodiment of a computer implemented drawing method in accordance with the disclosed embodiments. At 700, for each truss plate type, at 710 the positions of the teeth are modeled. Modeling includes correctly positioning the shape, size, and orientation of the teeth relative to the plate size. Each model is stored in a model library at 720. When a truss design application is creating truss design drawings, the engineering drawing for the each truss assembly is retrieved and for each truss plate specified in each drawing at 730. For each specified truss plate in each drawing at 740, the teeth markings are rendered on the truss component, with the markings corresponding to the position, orientation, and placement of the truss plate product. The method moves to the next component at 760.

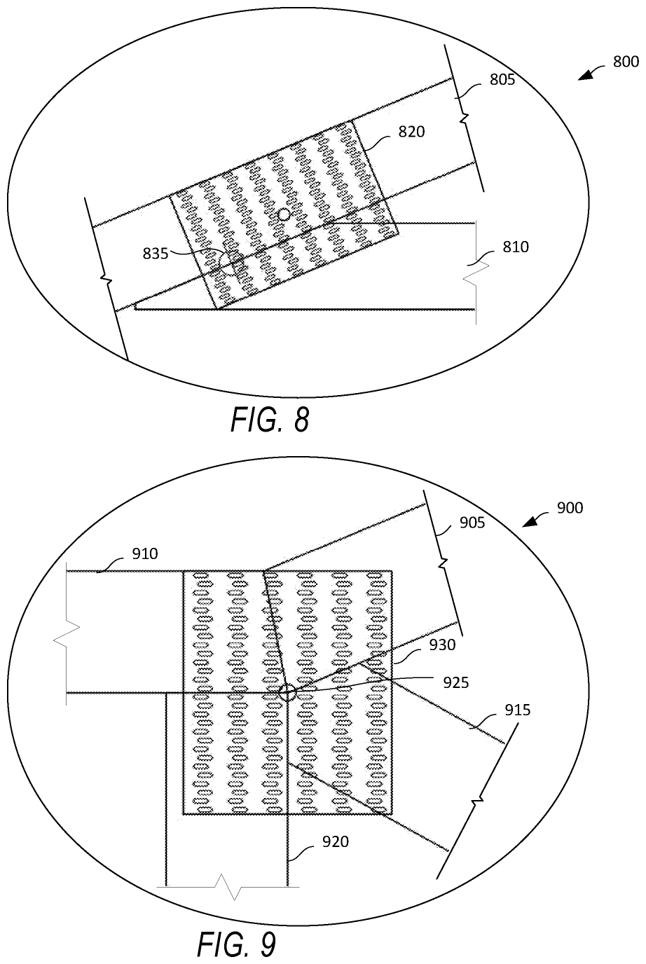

FIGS. 8-10 illustrate various enlarged portions of construction drawings illustrating how teeth are printed on drawings. FIG. 8 illustrates an enlarged portion 800 of a construction drawing showing connection of two components 805, 810 to be secured by a truss plate. The center of the connections is shown at 835. The drawing illustrates a printed plate 820 showing precisely the position and orientation of the plate. In FIG. 8, the plate illustration 820 is oriented at an angle matching the angle of component 805 relative to component 810, and relative to the center 825 of the connection.

FIG. 9 illustrates an enlarged portion 900 of a construction drawing showing connection of four truss components 905, 910, 915. 920, to be secured by a truss plate. The center of the connections is shown at 925. The drawing shows an illustration 930 of the truss plate showing precisely the position and orientation of the plate and including the position and orientation of the truss plate teeth. In FIG. 9, the plate illustration 930 is oriented relative to the center 925 of the connection.

FIG. 10 depicts another embodiment of the disclosed technology. FIG. 10 may represent either an enlarged portion of a construction drawing or an enlarged view of truss assembly components having truss plate teeth positions printed thereon. As illustrated therein, the teeth positions are only illustrated in the drawing on the components themselves. Where the figure illustrates components, it should be understood that the teeth positions would only be printed on the components themselves. In either case, the number, orientation, and position of the teeth positions enable accurate placement and orientation of the correct truss plate for use with the truss assembly.

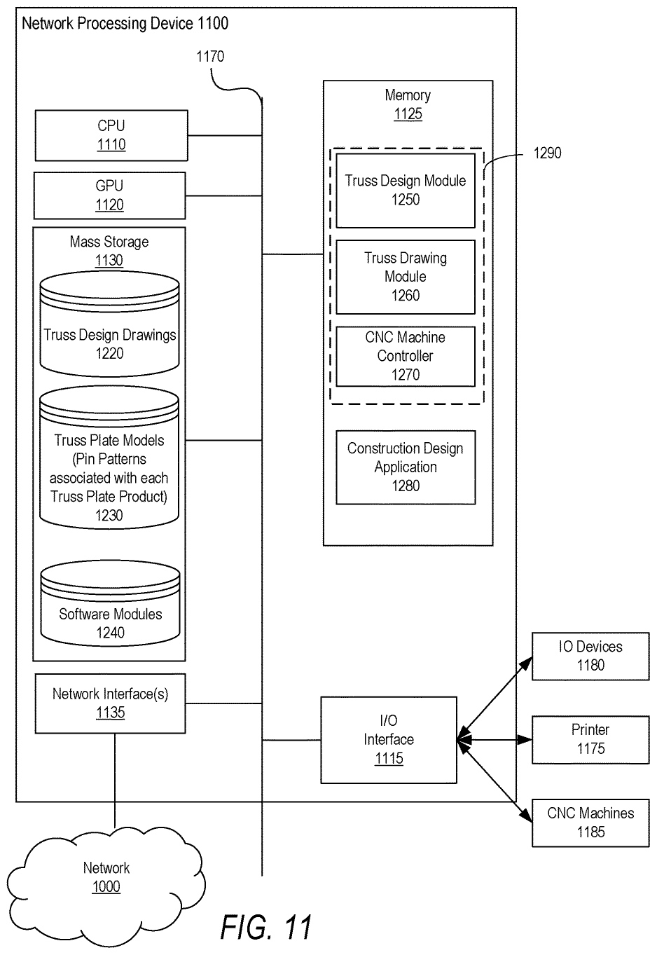

FIG. 11 illustrates a network processing device 1100 which may comprise any suitable processing device enabling aspects of the disclosed technology. The network processing device 1100 may be a desktop computer, server, mobile device, or integrated into a headset display device, or may be provided in a housing which is separate from but connected to a display, projector or augmented reality headset.

Device 1100 may comprise a central processing unit (CPU) 1110, a graphics processing unit (GPU) 1120, a memory 1125, a mass storage device 1130, and an I/O interface 1115 connected to a bus 1170. The I/O interface 1115 may be connected to I/O devices such as a keyboard, mouse, display, augmented reality headset or the like. The bus 1170 may be one or more of any type of several bus architectures including a memory bus or memory controller, a peripheral bus, or the like. A network interface 1135 enables the network processing device to communicate over a network 1000 with other processing devices and the Internet. In embodiments, network processing device 1100 may contain multiple instances of a component, such as multiple processing units, processors, memories, interfaces, etc.

The mass storage device 1130 may comprise any type of storage device configured to store data, programs, and other information and to make the data, programs, and other information accessible via the bus 1170. The mass storage device 1130 may comprise, for example, one or more of a solid-state drive, hard disk drive, a magnetic disk drive, an optical disk drive, or the like. The mass storage device 1130 includes instructions which when executed by the CPU (or processor) cause the processor to perform the methods described herein. The mass storage 1130 may include code in the form of application modules 1240 stored thereon, comprising instructions for causing the CPU to implement the components of the truss design module 1250, truss design module 1260 and, optionally, a CNC machine controller 1270, shown as instances in non-volatile memory 1125. The application modules 1240 may also include stored application for implementing construction designs which, when executed by the CPU and GPU, provide a construction design application 1280.

The CPU 1110 may comprise any type of electronic data processor. Memory 1125 may comprise any type of system memory such as static random-access memory (SRAM), dynamic random-access memory (DRAM), synchronous DRAM (SDRAM), read-only memory (ROM), a combination thereof, or the like. In an embodiment, memory 1125 may include ROM for use at boot-up, and DRAM for program and data storage for use while executing programs. In embodiments, the memory 1125 is non-transitory. In one embodiment, the memory 1125 includes computer-readable instructions that are executed by the processor(s) 1110 and 1120 to implement embodiments of the disclosed technology.

In one embodiment, the memory 1125 includes instances of truss design module 1250, truss design module 1260 and, optionally, a CNC machine controller 1270, and the construction design application 1280, all stored in nonvolatile memory as modules 1240. Stored versions of each of these components may be provided in mass storage 1130 in application modules comprising code instructing the CPU and GPU to implement applications and images associated with the applications on the display screens discussed herein. In embodiments, the construction design application may comprise, for example, Autodesk Revit, available from Autodesk Inc., San Francisco, CA. In embodiments, the truss design module may comprise Component Solutions® Truss Studio™ available from Simpson Strong-Tie, Pleasanton California, modified to incorporate the presently described methods.

In embodiments, the IO interface 1115 communicates with the aforementioned I/O devices 1180, one or more printers 1175 to generate construction drawings, and, optionally CNC machines 1185.

It is understood that the present subject matter may be embodied in many different forms and should not be construed as being limited to the embodiments set forth herein. Rather, these embodiments are provided so that this subject matter will be thorough and complete and will fully convey the disclosure to those skilled in the art. Indeed, the subject matter is intended to cover alternatives, modifications, and equivalents of these embodiments, which are included within the scope and spirit of the subject matter as defined by the appended claims. Furthermore, in the following detailed description of the present subject matter, numerous specific details are set forth in order to provide a thorough understanding of the present subject matter. However, it will be clear to those of ordinary skill in the art that the present subject matter may be practiced without such specific details.

Aspects of the present disclosure are described herein with reference to flowchart illustrations and/or block diagrams of methods, apparatuses (systems) and computer program products according to embodiments of the disclosure. It will be understood that where blocks of the flowchart illustrations and/or block diagrams, and combinations of blocks in the flowchart illustrations and/or block diagrams, describe computer implemented processes, these processes can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The aspects of the disclosure herein were chosen and described in order to best explain the principles of the disclosure and the practical application, and to enable others of ordinary skill in the art to understand the disclosure with various modifications as are suited to the particular use contemplated.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A method of assembling a wood truss having truss components which are joined by truss plates, each truss plate having a plurality of teeth, comprising:
generating construction drawings including graphical representations of the plurality of teeth at positions and orientations relative to junctions between components to which the plate is to be secured in an assembled wood truss;
placing the truss components in positions as illustrated in the drawings on a work surface;
aligning a truss plate matching the graphical representation of the plurality of teeth for each of the junctions between truss components to be secured; and
applying pressure to each plate to secure each junction.

2. The method of claim 1 wherein each truss plate includes a surface having a face, wherein the plurality of teeth are punched from the truss plate in pairs of teeth and formed at right angles to the face of the plate so that two teeth per hole occur in rows along the face.

3. The method of claim 2 wherein each graphical representation of the truss plate includes a representation of each punched hole of the pairs of teeth.

4. The method of claim 1 wherein the placing comprises:
printing the construction drawings; and
aligning the truss plate by matching the placement and orientation of the teeth of each truss plate to the graphical representation of the respective plate on the printed construction drawings.

5. The method of claim 1 wherein the placing comprises:
rendering the construction drawings on a graphical display; and
aligning the truss plate by matching the placement and orientation of the teeth of each truss plate to the rendered drawing of the respective plate.

6. The method of claim 1 wherein the placing comprises:
rendering the construction drawings on a graphical projector display; and
aligning the truss plate by matching the placement and orientation of the teeth of each truss plate to the rendered drawing on the graphical projector display.

7. The method of claim 1 wherein the method further includes:
printing truss plate teeth positions on the components; and
aligning the truss plate by matching the placement and orientation of the plate to the printed positions on the components.

8. A computer implemented method of assembling a wood truss having truss components secured by truss plates, each truss plate having a plurality of teeth, comprising:
designing a construction project including one or more wood trusses, and a plurality of truss plate types each having a plurality of teeth;
creating, in a computer implemented truss design system, a graphical model of the positions of teeth relative to the face of the each truss plate type;
storing the graphical model of each truss plate type in a data library;
in the computer implemented truss design system, for each truss plate in a truss assembly in the construction project, retrieving the graphical model and rendering teeth marks on a construction drawing, the teeth markings corresponding to the position and orientation of the teeth; and
rendering the drawing to an display to allow a truss assembler to construct the truss assembly.

9. The method of claim 8 wherein each truss plate includes a surface having a face and the teeth are punched from the truss plate in pairs and formed at right angles to the face of the parent metal so that two teeth per hole occur in rows along the face.

10. The method of claim 9 wherein each graphical representation of the truss plate includes a representation of each of the punched portion of the pairs of teeth.

11. The method of claim 8 wherein the rendering comprises:
printing the construction drawings to allow the assembler to align each of the truss plates by matching the placement and orientation of the plate to the printed construction drawings.

12. The method of claim 8 wherein the rendering comprises: rendering the construction drawings on a graphical display to allow the assembler to align each of the truss plates by matching the placement and orientation of the plate to rendered construction drawings on the graphical display.

13. The method of claim 8 wherein the rendering comprises: rendering the construction drawings on a projection display to allow the assembler to align each of the truss plates by matching the placement and orientation of the plate to rendered construction drawings on the projection display.

14. The method of claim 1 wherein the rendering comprises printing truss plate teeth positions on the components to allow the assembler to align each of the truss plates by matching the placement and orientation of the plate to the printed positions on the components.
